(19) United States
(12) Patent Application Publication
(10) Pub. No.: US 2015/0179896 A1
(43) Pub. Date: Jun. 25, 2015

(54) PACKAGE STRUCTURE OF LIGHT EMITTING DIODE

(71) Applicant: Genesis Photonics Inc., Tainan City (TW)

(72) Inventors: Jing-En Huang, Tainan City (TW); Po-Jen Su, Taipei City (TW); Chih-Ling Wu, New Taipei City (TW); Shao-Ying Ting, Tainan City (TW); Yi-Ru Huang, Tainan City (TW); Yu-Yun Lo, Tainan City (TW)

(21) Appl. No.: 14/576,218

(22) Filed: Dec. 19, 2014

(30) Foreign Application Priority Data
Dec. 20, 2013 (TW) 102147571

(51) Int. Cl. H01L 33/48; H01L 33/62

(52) U.S. Cl. CPC H01L 33/486; H01L 33/62

(57) ABSTRACT

A package structure of light emitting diode includes a substrate and a light emitting diode die. The substrate has an upper surface and a lower surface opposite to each other. Two upper metal pads without mutual conduction are arranged on the upper surface. Two lower metal pads without mutual conduction are arranged on the lower surface. The light emitting diode die is disposed across the two upper metal pads. The light emitting diode die has a first electrode and a second electrode electrically connected to the two upper metal pads respectively. Wherein an orthographic projection area of one of the lower metal pads is greater than or equal to an orthographic projection area of the light emitting diode die, and the orthographic projection area of the light emitting diode die is totally located within the orthographic projection area of one of the lower metal pads.

### BACKGROUND OF THE DISCLOSURE

1. Field of the Disclosure

The present disclosure relates to a package structure of light emitting diode, and more particularly, to a package structure of light emitting diode capable of improving heat dissipation efficiency.

2. Description of the Prior Art

When an electronic product is being operated, the current in circuits may generate unnecessary heat due to impedance. If the heat accumulated in the electronic components of the electronic product cannot be dissipated immediately, the electronic components may be damaged due to rising temperature. Therefore, heat dissipation efficiency is a significant issue for electronic products, especially for light emitting diodes. When the temperature of a light emitting diode rises, the light emitting efficiency of the light emitting diode may decrease apparently and the life span of the light emitting diode may also decrease. As light emitting diodes are applied to various illumination devices gradually, the heat dissipation efficiency of the light emitting diodes may become significant issues.

### SUMMARY OF THE DISCLOSURE

The disclosure is to provide a package structure of light emitting diode capable of improving heat dissipation efficiency.

A package structure of light emitting diode of the present disclosure comprises a substrate and a light emitting diode die. The substrate has an upper surface and a lower surface opposite to each other. Two upper metal pads without mutual conduction are arranged on the upper surface. Two lower metal pads without mutual conduction are arranged on the lower surface. The light emitting diode die is disposed across the two upper metal pads. The light emitting diode die has a first electrode and a second electrode electrically connected to the two upper metal pads respectively. Wherein an orthographic projection area of one of the lower metal pads is greater than or equal to an orthographic projection area of the light emitting diode die, and the orthographic projection area of the light emitting diode die is totally located within the orthographic projection area of one of the lower metal pads.

In contrast to the prior art, in the package structure of light emitting diode of the present disclosure, the orthographic projection area of one of the lower metal pads is greater than or equal to the orthographic projection area of the light emitting diode die, and the orthographic projection area of the light emitting diode die is totally located within the orthographic projection area of one of the lower metal pads, such that the package structure of light emitting diode has a shortest heat dissipation path, in order to improve heat dissipation efficiency of the package structure of light emitting diode, and solve the heat dissipation problem of the light emitting diode of the prior art.

These and other objectives of the present disclosure will no doubt become obvious to those of ordinary skill in the art after reading the detailed description of the following embodiments those are illustrated in the various figures and drawings.

### BRIEF DESCRIPTION OF THE DRAWINGS

FIG. 1 is a diagram showing a package structure of light emitting diode according to a first embodiment of the present disclosure.

FIG. 2 is a diagram showing arrangement of orthographic projection areas of related components on a substrate of the package structure of light emitting diode of the present disclosure.

FIG. 3 is a diagram showing a package structure of light emitting diode according to a second embodiment of the present disclosure.

FIG. 4 is a diagram showing a package structure of light emitting diode according to a third embodiment of the present disclosure.

FIG. 5 is a diagram showing a package structure of light emitting diode according to a fourth embodiment of the present disclosure.

FIG. 6 is a diagram showing a light emitting diode module of the present disclosure.

### DETAILED DESCRIPTION

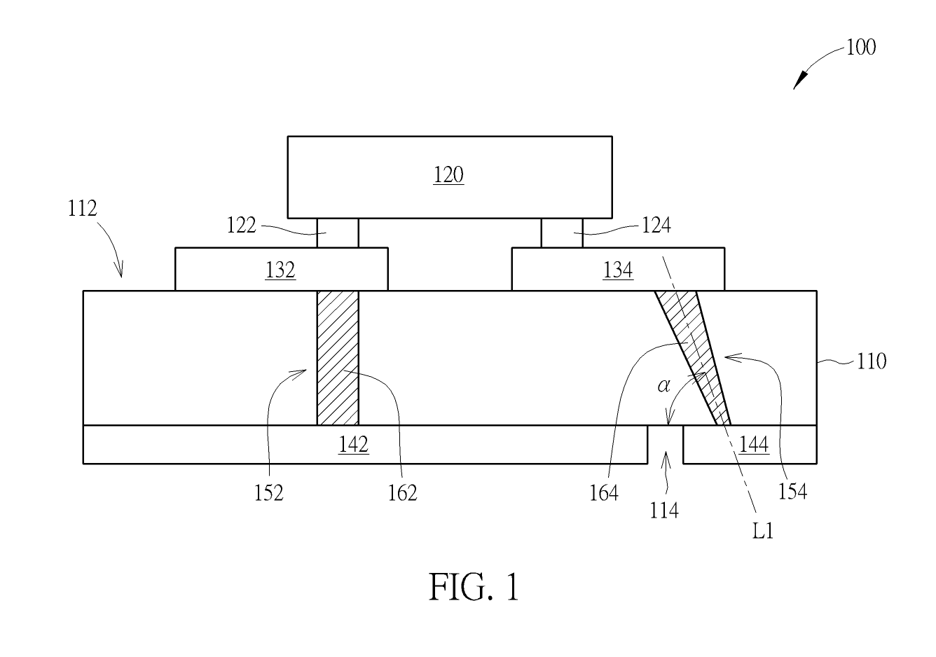

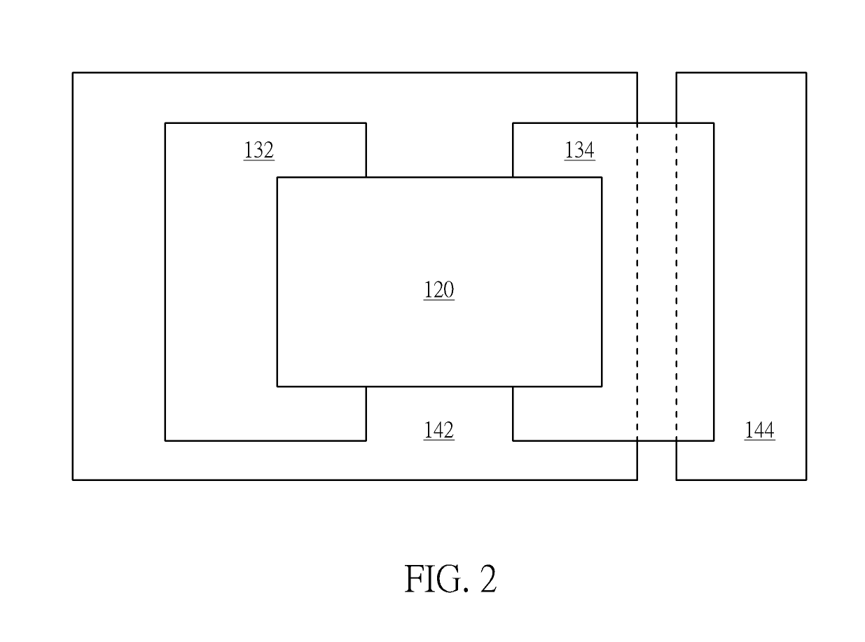

Please refer to FIG. 1 and FIG. 2 together. FIG. 1 is a diagram showing a package structure of light emitting diode according to a first embodiment of the present disclosure. FIG. 2 is a diagram showing arrangement of orthographic projection areas of related components on a substrate of the package structure of light emitting diode of the present disclosure. As shown in FIG. 1, the package structure 100 of light emitting diode of the present disclosure comprises a substrate 110 and a light emitting diode die 120. The substrate 110 has an upper surface 112 and a lower surface 114 opposite to each other. Two upper metal pads 132, 134 without mutual conduction are arranged on the upper surface 112 of the substrate 110, and two lower metal pads 142, 144 without mutual conduction are arranged on the lower surface 114 of the substrate 110. The light emitting diode die 120 is disposed across the two upper metal pads 132, 134. The light emitting diode die 120 has a first electrode 122 and a second electrode 124 electrically connected to the two upper metal pads 132, 134 respectively

The package structure 100 of light emitting diode of the present disclosure further comprises two through holes 152, 154 and two metal conductive pillars 162, 164. The through holes 152, 154 are arranged in the substrate, and each of the through holes 152, 154 has an upper opening formed on the upper surface 112 and a corresponding lower opening formed on the lower surface 114. The metal conductive pillars 162, 164 are respectively arranged in the through holes 152, 154 for electrically connecting the upper metal pads 132, 134 and the lower metal pads 142, 144. The lower metal pads 142, 144 can receive voltages with different polarities respectively, for driving the light emitting diode die to emit light.

As shown in FIG. 2, in order to improve heat dissipation efficiency, in the package structure 100 of light emitting diode of the present disclosure, an orthographic projection area of one of the lower metal pads 142, 144 is greater than or equal to the orthographic projection area of the light emitting diode die 120, and the orthographic projection area of the light emitting diode die 120 is totally located within the orthographic projection area of one of the lower metal pads 142, 144. The larger orthographic projection area of the lower metal pad 142 can be 1 to 100 times as big as the orthographic projection area of the light emitting diode die 120, so as to provide better heat dissipation efficiency by effectively utilizing the lower surface 114 of the substrate 110.

It is noted that the orthographic projection areas mentioned through the description are orthographic projection areas projected on the substrate 110, thus no further explanation is provided.

According to the above arrangement, heat generated by the light emitting diode die 120 when emitting light can be guided to the lower metal pads 142, 144 through the metal conductive pillars 162, 164 and the substrate 110. Moreover, a distance between the lower metal pad 142 having the larger orthographic projection area and the light emitting diode die 120 is a shortest distance, and the metal conductive pillars 162, 164 are embedded inside the substrate 110, therefore, the heat generated by the light emitting diode die 120 when emitting light can be conducted to the lower metal pad 142 having the larger orthographic projection area as fast as possible, so as to improve heat dissipation efficiency of the package structure 100 of light emitting diode of the present disclosure. More particularly, the metal conductive pillars 162, 164, the upper metal pads 132, 134 and the lower metal pads 142, 144 can be formed integrally, and made of gold, copper, aluminum, silver, tin, alloy or any combination of the above metal materials.

In addition, an area of one of the upper opening is greater than an area of the corresponding lower opening, this is because the upper opening is closer to the light emitting diode die 120, which has a higher temperature, than the lower opening is. Therefore, the upper opening provides a larger contact area to quickly conduct the heat to the lower metal pads. Moreover, the metal conductive pillars 162, 164 are formed by filling metal material into the through holes 152, 154 via the upper openings, the upper openings having bigger areas can facilitate formation of the through holes and filling of the metal conductive pillars. In a preferred embodiment, a diameter of one of the through holes 152, 154 is gradually decreased from the upper surface 112 to the lower surface 114. In addition, an angle a between a central axis L1 of the metal conductive pillar 164 and the lower surface 114 of the substrate 110 is greater than 10 degrees and smaller than 90 degrees, that is to say, the metal conductive pillar 164 is inclined, such that space inside the substrate 110 can be effectively used for satisfying requirement of package miniaturization.

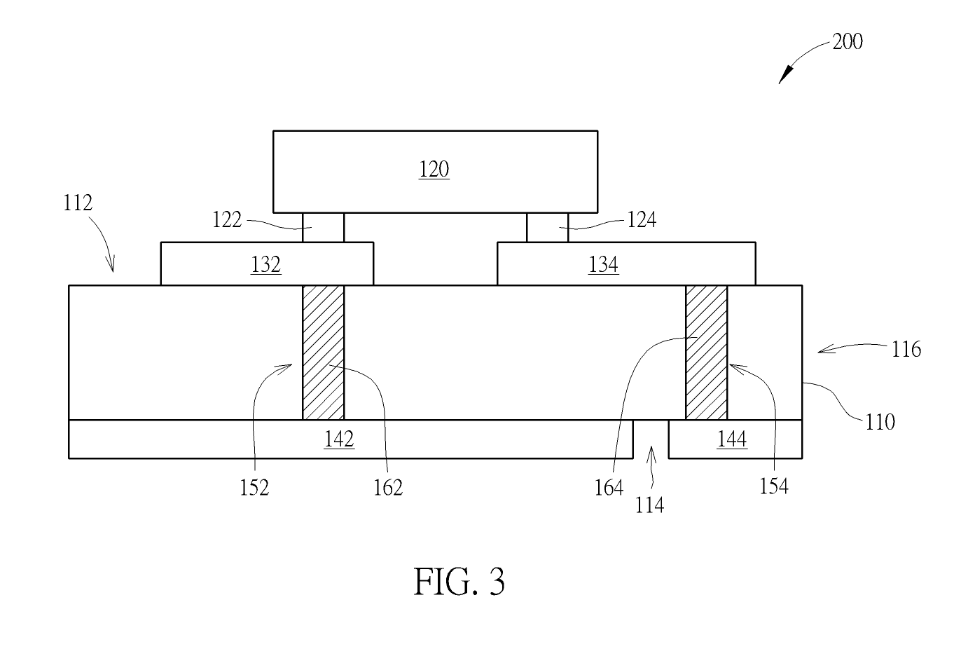

Please refer to FIG. 3. FIG. 3 is a diagram showing a package structure 200 of light emitting diode according to a second embodiment of the present disclosure. A difference between FIG. 3 and FIG. 2 is that diameters of the through holes 152, 154 in FIG. 3 are uniform, in order to simplify manufacturing processes. In addition, when the diameters of the through holes 152, 154 are uniform, the metal conductive pillars 164 has a uniform cross-sectional area, such that the metal conductive pillars 164 has a more even heat conduction rate.

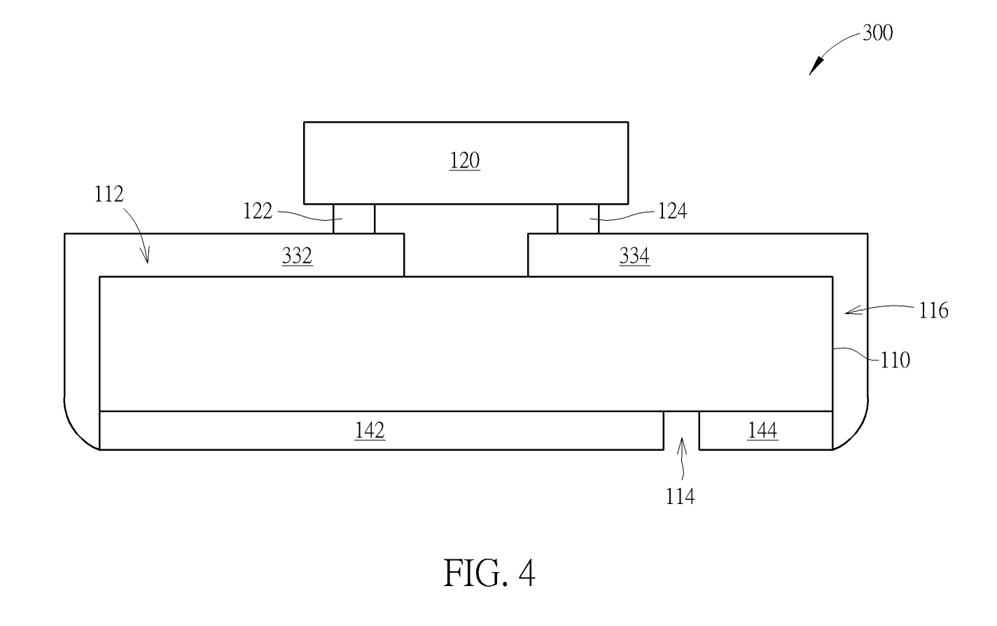

Please refer to FIG. 4. FIG. 4 is a diagram showing a package structure 300 of light emitting diode according to a third embodiment of the present disclosure. As shown in FIG. 4, the upper metal pads 332, 334 are extended along the upper surface 112 and sidewalls 116 of the substrate 110 to connect to the corresponding lower metal pads 142, 144. In the embodiment of FIG. 4, the orthographic projection area of one of the lower metal pads 142, 144 is greater than or equal to the orthographic projection area of the light emitting diode die 120, and the orthographic projection area of the light emitting diode die 120 is totally located within the orthographic projection area of one of the lower metal pads 142, 144. The larger orthographic projection area of the lower metal pad 142 is preferred to be 1 to 100 times as big as the orthographic projection area of the light emitting diode die 120.

Similarly, the heat generated by the light emitting diode die 120 when emitting light can be guided to the lower metal pads 142, 144 through the upper metal pads 332, 334 and the substrate 110. Since a distance between the lower metal pad 142 having the larger orthographic projection area and the light emitting diode die 120 is a shortest distance, the package structure 300 of light emitting diode has a shortest heat dissipation path. Therefore, the heat generated by the light emitting diode die 120 when emitting light can be conducted to the lower metal pad 142 having the larger orthographic projection area as fast as possible, so as to improve heat dissipation efficiency of the package structure 300 of light emitting diode of the present disclosure.

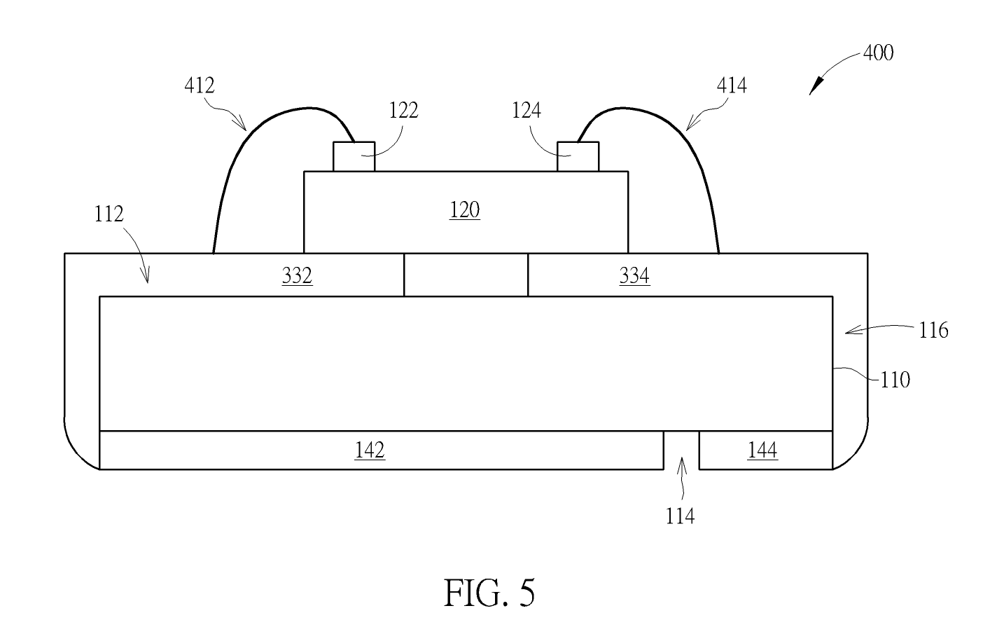

Please refer to FIG. 5. FIG. 5 is a diagram showing a package structure 400 of light emitting diode according to a fourth embodiment of the present disclosure. As shown in FIG. 5, the first electrode 122 and the second electrode 124 of the light emitting diode die 120 are electrically connected to the upper metal pads 332, 334 through wires 412, 414 respectively, and the upper metal pads 332, 334 are extended along the upper surface 112 and sidewalls 116 of the substrate 110 to connect to the corresponding lower metal pads 142, 144. In the embodiment of FIG. 5, the light emitting diode die 120 can be a horizontal light emitting diode die. The orthographic projection area of one of the lower metal pads 142, 144 is greater than or equal to the orthographic projection area of the light emitting diode die 120, and the orthographic projection area of the light emitting diode die 120 is totally located within the orthographic projection area of one of the lower metal pads 142, 144. The larger orthographic projection area of the lower metal pad 142 is preferred to be 1 to 100 times as big as the orthographic projection area of the light emitting diode die 120.

Similarly, the heat generated by the light emitting diode die 120 when emitting light can be guided to the lower metal pads 142, 144 through the upper metal pads 332, 334 and the substrate 110. Since a distance between the lower metal pad 142 having the larger orthographic projection area and the light emitting diode die 120 is a shortest distance, the package structure 400 of light emitting diode has a shortest heat dissipation path. Therefore, the heat generated by the light emitting diode die 120 when emitting light can be conducted to the lower metal pad 142 having the larger orthographic projection area as fast as possible, so as to improve heat dissipation efficiency of the package structure 400 of light emitting diode of the present disclosure.

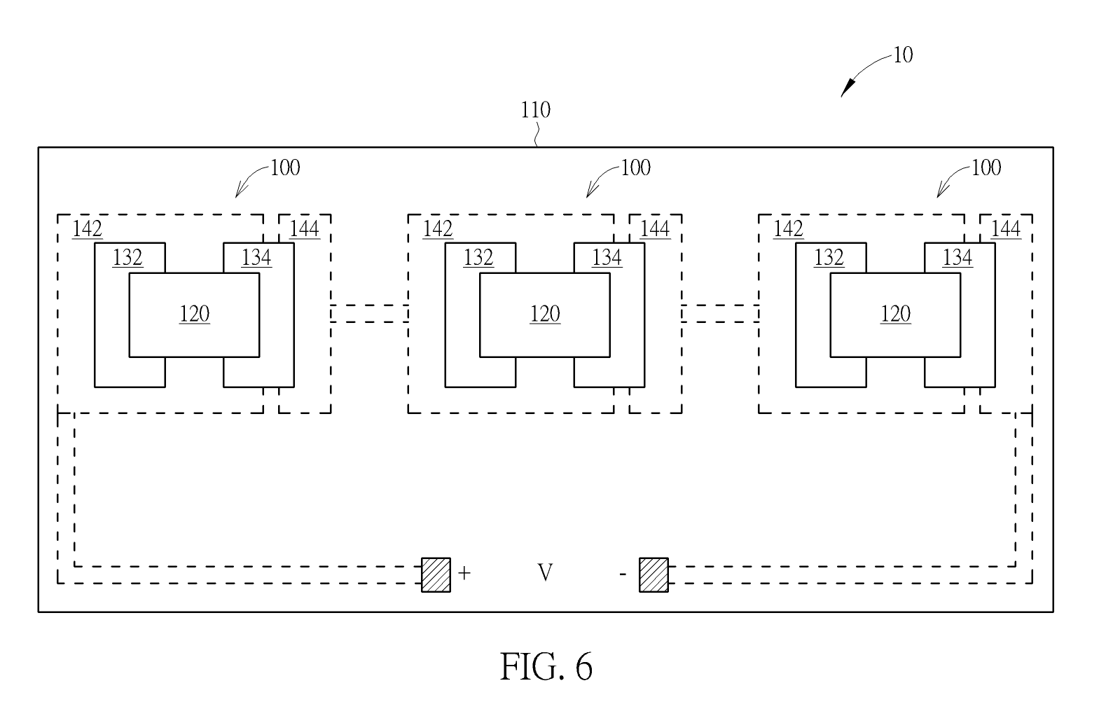

Please refer to FIG. 6. FIG. 6 is a diagram showing a light emitting diode module of the present disclosure. As shown in FIG. 6, the light emitting diode module 10 of the present disclosure comprises a substrate 110, a plurality of light emitting diode dies 120, a plurality of corresponding upper metal pads 132, 134, and a plurality of corresponding lower metal pads 142, 144. The plurality of light emitting diode dies 120 can be electrically connected in series or in parallel through the corresponding lower metal pads 142, 144. An orthographic projection area of one of the lower metal pads 142, 144 is greater than or equal to the orthographic projection area of the light emitting diode die 120, and the orthographic projection area of the light emitting diode die 120 is totally located within the orthographic projection area of one of the lower metal pads 142, 144. The larger orthographic projection area of the lower metal pad 142 is preferred to be 1 to 100 times as big as the orthographic projection area of the corresponding light emitting diode die 120. According to the above arrangement, the light emitting diode module 10 of the present disclosure has better heat dissipation efficiency.

In addition, in the embodiments of the present disclosure, the light emitting diode die 120 can be a flip-chip light emitting diode die, and the first electrode 122 and the second electrode 124 of the light emitting diode die 120 are electrically connected to the upper metal pads by eutectic bonding. The substrate 110 can be made of aluminum nitride or aluminum oxide, in order to further improve heat dissipation efficiency.

In contrast to the prior art, in the package structure of light emitting diode of the present disclosure, the orthographic projection area of one of the lower metal pads is greater than or equal to the orthographic projection area of the light emitting diode die, and the orthographic projection area of the light emitting diode die is totally located within the orthographic projection area of one of the lower metal pads, thus the distance between the lower metal pad having the larger orthographic projection area and the light emitting diode die is a shortest distance, such that the package structure of light emitting diode has a shortest heat dissipation path, in order to improve heat dissipation efficiency of the package structure of light emitting diode, and solve the heat dissipation problem of the light emitting diode of the prior art.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A package structure of light emitting diode comprising:
a substrate, having an upper surface and a lower surface opposite to each other, wherein two upper metal pads without mutual conduction are arranged on the upper surface, and two lower metal pads without mutual conduction are arranged on the lower surface; and
a light emitting diode die, disposed across the two upper metal pads, the light emitting diode die having a first electrode and a second electrode electrically connected to the two upper metal pads respectively;
wherein an orthographic projection area of one of the lower metal pads is greater than or equal to an orthographic projection area of the light emitting diode die, and the orthographic projection area of the light emitting diode die is totally located within the orthographic projection area of one of the lower metal pads.

2. The package structure of claim 1, wherein the orthographic projection area of one of the lower metal pads is 1 to 100 times as big as the orthographic projection area of the light emitting diode die.

3. The package structure of claim 1 further comprising:
at least two through holes, arranged in the substrate, each of the through holes having an upper opening formed on the upper surface and a lower opening formed on the lower surface; and
two metal conductive pillars, arranged in the through holes for electrically connecting the upper metal pads and the lower metal pads.

4. The package structure of claim 3, wherein an area of one of the upper opening is greater than an area of the corresponding lower opening.

5. The package structure of claim 3, wherein a diameter of one of the through holes is gradually decreased from the upper surface to the lower surface.

6. The package structure of claim 3, wherein an angle between a central axis of one of the metal conductive pillars and the lower surface is greater than 10 degrees and smaller than 90 degrees.

7. The package structure of claim 3, wherein diameters of the through holes are uniform.

8. The package structure of claim 1, wherein the upper metal pads are extended to sidewalls of the substrate to connect to the lower metal pads.

9. The package structure of claim 1, wherein the light emitting diode die is a flip-chip light emitting diode die.

10. The package structure of claim 1, wherein the first electrode and the second electrode of the light emitting diode die are electrically connected to the two upper metal pads by eutectic bonding.

11. The package structure of claim 1, wherein the lower metal pads receive voltages with different polarities respectively.

12. The package structure of claim 1, wherein the substrate is made of aluminum nitride or aluminum oxide.
